(19) United States
(12) Patent Application Publication
(10) Pub. No.: US 2024/0253978 A1
(43) Pub. Date: Aug. 1, 2024

(54) WIRING BOARD ASSEMBLY, LID ASSEMBLY, PACKAGE SET, AND METHOD FOR MANUFACTURING ELECTRONIC COMPONENT

(71) Applicant: KYOCERA Corporation, Kyoto-shi, Kyoto (JP)

(72) Inventor: Koutarou NAKAMOTO, Kyoto-shi (JP)

(73) Assignee: KYOCERA Corporation, Kyoto-shi, Kyoto (JP)

(21) Appl. No.: 18/565,918

(22) PCT Filed: Jun. 22, 2022
(86) PCT No.: PCT/JP2022/024803

§ 371 Date: Nov. 30, 2023

(30) Foreign Application Priority Data
Jun. 29, 2021 (JP) 2021-108104

(51) Int. Cl. B81C 1/00; B81B 7/00; H01L 21/52; H01L 21/56

(52) U.S. Cl. CPC B81C 1/00269; H01L 21/52; H01L 21/561; B81B 7/0061; B81B 2201/0257; B81C 2203/0109

(57) ABSTRACT

The present disclosure provides a wiring board assembly, a lid assembly, and a package set including the wiring board assembly and the lid assembly, which do not require singulation by cutting an electronic component after sealing. The wiring board assembly includes a frame body, a sheet closing the frame body, and a plurality of wiring boards adhered to one surface of the sheet.

### TECHNICAL FIELD

The present disclosure relates to a wiring board assembly in which a plurality of wiring boards are integrally formed, a lid assembly in which a plurality of lids are integrally formed, a package set including the wiring board assembly and the lid assembly, and a method for manufacturing an electronic component.

### BACKGROUND OF INVENTION

Patent Document 1 discloses a method for manufacturing an electronic component which is made of an insulator and in which a recess of a wiring board is sealed with a lid after accommodating an electric electronic element in the recess. In the manufacturing method, a lid assembly is placed on a wiring board assembly in which wiring boards are arrayed, and the lids are bonded to the wiring boards.

### CITATION LIST

### Patent Literature

Patent Document 1: JP 2009-33613 A

### SUMMARY

A wiring board assembly of a non-limiting example in the present disclosure includes a frame body, a sheet that closes the frame body, and a plurality of wiring boards adhered to one surface of the sheet.

A lid assembly of a non-limiting example in the present disclosure includes a frame body, a sheet that closes the frame body, and a plurality of lids adhered to one surface of the sheet.

A package set of a non-limiting example in the present disclosure includes the wiring board assembly described above and the lid assembly described above, in which the plurality of lids are located on the one surface of the sheet included in the lid assembly in correspondence with the plurality of wiring boards.

A method for manufacturing an electronic component of a non-limiting example in the present disclosure includes preparing a wiring board assembly including a first frame body, a first sheet that closes the first frame body, and a plurality of wiring boards adhered to one surface of the first sheet. The method includes mounting each of a plurality of electronic elements on a respective wiring board of the plurality of wiring boards of the wiring board assembly, sealing the electronic elements, and peeling off the plurality of wiring boards from the first sheet.

A method for manufacturing an electronic component of a non-limiting example in the present disclosure includes preparing a wiring board assembly including a first frame body, a first sheet that closes the first frame body, and a plurality of wiring boards adhered to one surface of the first sheet. The method includes preparing a lid assembly including a second frame body, a second sheet that closes the second frame body, and a plurality of lids adhered to one surface of the second sheet. The method includes: mounting each of a plurality of electronic elements on a respective wiring board of the plurality of wiring boards of the wiring board assembly; and overlapping the lid assembly on the wiring board assembly, the plurality of lids of the lid assembly being opposite to the plurality of wiring boards on which the electronic elements are mounted. The method includes sealing the electronic elements by bonding the plurality of lids to the plurality of wiring boards, peeling off the plurality of wiring boards from the first sheet, and peeling off the plurality of lids from the second sheet.

### BRIEF DESCRIPTION OF THE DRAWINGS

FIG. 1 is a plan view illustrating a wiring board assembly (first assembly) in a non-limiting embodiment of the present disclosure.

FIG. 2 is a broken cross-sectional view along line II-II in FIG. 1.

FIG. 3 is a cross-sectional view illustrating a first assembly.

FIG. 4 is a plan view illustrating a lid assembly (second assembly).

FIG. 5 is a cross-sectional view illustrating a second assembly.

FIG. 6 is a cross-sectional view illustrating a method for manufacturing an electronic component.

FIG. 7 is a cross-sectional view illustrating a method for manufacturing an electronic component.

FIG. 8 is an explanatory view for explaining a method for overlapping a first assembly and a second assembly.

FIG. 9 is an explanatory view for explaining a method for overlapping a first assembly and a second assembly.

FIG. 10 is a cross-sectional view illustrating a method for manufacturing an electronic component.

FIG. 11 is a cross-sectional view illustrating a method for manufacturing an electronic component.

FIG. 12 is a cross-sectional view illustrating a method for manufacturing an electronic component.

FIG. 13 is a cross-sectional view illustrating a method for manufacturing an electronic component.

FIG. 14 is a cross-sectional view illustrating a state where a first sheet is peeled off from an electronic component.

FIG. 15 is a cross-sectional view illustrating a state where an electronic component is peeled off from a first sheet.

FIG. 16 is a plan view illustrating a first assembly in a state where a wiring board is peeled off from a first sheet.

FIG. 17 is a cross-sectional view illustrating a variation of an electronic component.

FIG. 18 is a cross-sectional view illustrating another variation of an electronic component.

FIG. 19 is a cross-sectional view illustrating a variation of a method for manufacturing an electronic component.

FIG. 20 is a cross-sectional view for explaining a step of sealing an electronic element with a resin in the variation of the above manufacturing method.

FIG. 21 is a cross-sectional view for explaining another step of sealing an electronic element with a resin in the variation of the above manufacturing method.

FIG. 22 is a cross-sectional view illustrating another variation of a method for manufacturing an electronic component.

FIG. 23 is a cross-sectional view illustrating still variation of a method for manufacturing an electronic component.

FIG. 24 is a cross-sectional view for explaining a step of sealing an electronic element with a resin in still another variation of the above manufacturing method.

### DESCRIPTION OF EMBODIMENTS

In Patent Document 1, depending on the dimensional accuracy of the assembly of wiring boards, the position of each wiring board in the assembly of the wiring boards may vary, and the position of a lid, an electronic element, or the like may be displaced. An aspect of the present disclosure provides a wiring board assembly, a lid assembly, and a package set including the wiring board assembly and the lid assembly that enable mounting and sealing an electronic element with high accuracy.

Detailed description will be given below of a wiring board assembly, a lid assembly, a package set, and a method for manufacturing an electronic component of an embodiment that is an example of the present disclosure with reference to the diagrams. However, each of the figures, which will be referred to below, is a simplified representation of only main members necessary for description of the embodiments. Consequently, the wiring board assembly, the lid assembly, and the package set may include any constituent member not illustrated in each of the diagrams referred to. The dimensions of the members in the drawings do not faithfully represent the actual dimensions of the constituent members, the dimension ratios of the members, or the like.

A wiring board according to the present disclosure is at least a part of a package of an electronic component. An electronic component can be manufactured by mounting an electronic element on a wiring board and sealing the electronic element with a lid, a resin, or the like. When sealing using a lid, in an aspect according to the present disclosure, an electronic component is manufactured by overlapping a wiring board assembly (first assembly) in which a plurality of wiring boards are arrayed and a lid assembly (second assembly) in which a plurality of lids are arrayed, and sealing an electronic element.

### First Assembly (Wiring Board Assembly)

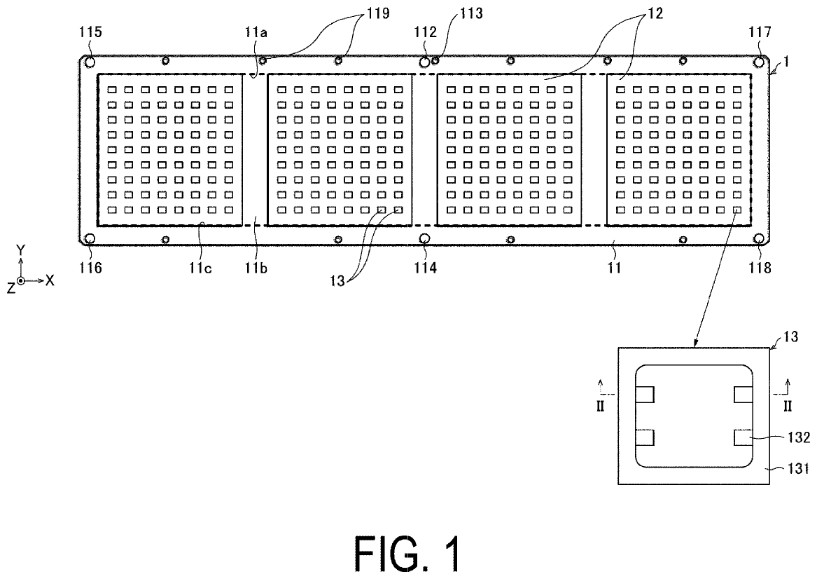

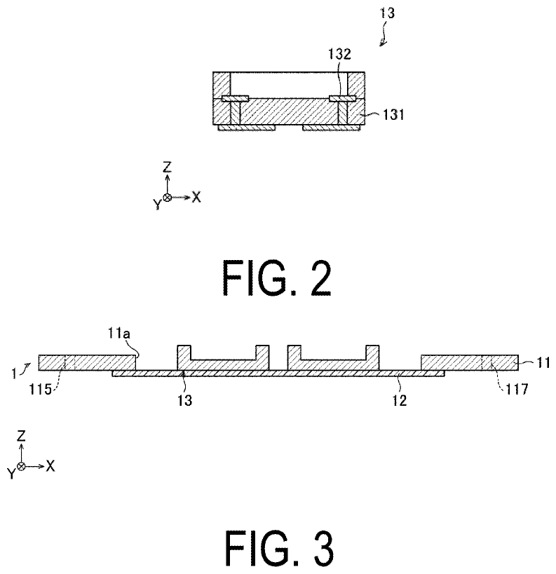

FIG. 1 is a plan view illustrating a wiring board assembly (hereinafter, referred to as a first assembly 1). FIG. 2 is a broken cross-sectional view along line II-II of a wiring board 13 illustrated in FIG. 1. FIG. 3 is a cross-sectional view illustrating the first assembly 1. The first assembly 1 includes a first frame body 11 having a rectangular shape, a first sheet 12 closing the first frame body 11, and a plurality of wiring boards 13 adhered to one surface of the first sheet 12. As illustrated in FIG. 3, the first frame body 11 and the wiring boards 13 are adhered to an identical surface of the first sheet 12. In FIG. 3, for the sake of simplicity, two wiring boards 13 are illustrated in an opening 11a and a plurality of wiring boards 13 between the two wiring boards 13 are omitted. Also in the other cross-sectional views, a plurality of wiring boards 13 between the two wiring boards 13 or a plurality of lids 23 between two lids 23 are omitted. In FIG. 3, a wiring conductor 132 included in the wiring board 13 is omitted. This is also true for other drawings illustrating the cross-section of the first assembly 1.

### First Frame Body

The first frame body 11 is made of a metal such as SUS or Cu. A synthetic resin such as engineering plastic having high strength and high heat resistance may also be used. When SUS is used as the material of the first frame body 11, the first frame body 11 has heat resistance to heating at the time of sealing an electronic element, high rigidity, and high corrosion resistance. The first frame body 11 has, for example, a rectangular shape in which the length in an X-axis direction is longer than the length in a Y-axis direction. Both an outer peripheral edge and an inner peripheral edge of the first frame body 11 each have a rectangular shape in a plan view. Examples of an external size of the first frame body 11 include a case where the length in the X-axis direction is 100 mm to 300 mm and the length in the Y-axis direction is 40 mm to 80 mm. The external size of the first frame body 11 can be easily set in accordance with an allowable range of mounting equipment.

The first frame body 11 has the opening 11a. In order to reinforce the strength of the first frame body 11, the first frame body 11 has three beams 11b that bridge a peripheral edge of the opening 11a in the Y-axis direction and are arranged at substantially equal intervals along the X-axis direction. The opening 11a is divided into four openings 11c by the beams 11b. In other words, the first frame body 11 has the four openings 11c. The opening 11a of the first frame body 11 is not limited to the case of being divided into four, and may be one without being divided or may be divided into a number other than four. When the opening 11a is large, since the strength of the first frame body 11 is low, the first frame body 11 may have a plurality of openings. When the first frame body 11 has a shape elongated in the X-axis direction as illustrated in FIG. 1, a plurality of openings may be arrayed in the X-axis direction at intervals. A plurality of openings may be arrayed in the Y-axis direction depending on the shape and size.

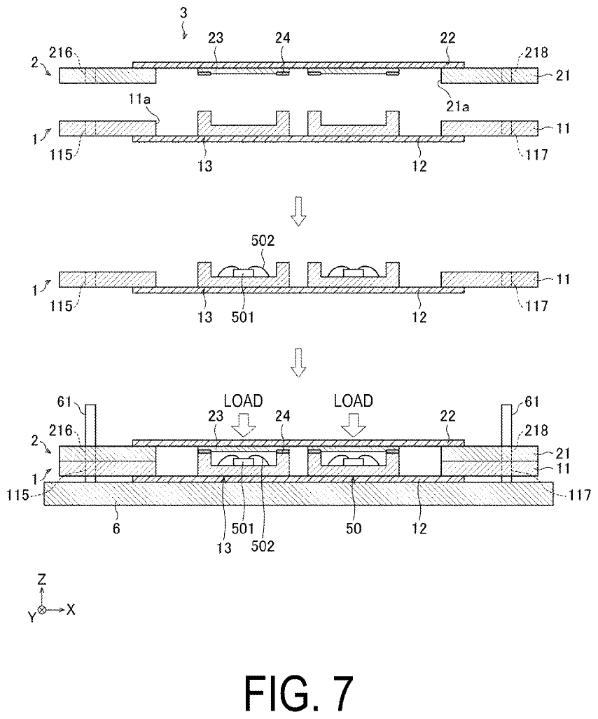

From the viewpoint of securing an adhesive margin for adhering the first sheet 12 and securing the strength, the width of the first frame body 11 (distance between the outer peripheral edge of the first frame body 11 and an outer peripheral edge of the opening 11a) may be 3 mm to 10 mm. The thickness of the first frame body 11 may be about half the total thickness of the wiring board 13 and the lid 23 of a lid assembly (hereinafter, referred to as a second assembly 2) to be described below, or may be about 0.2 mm to 1 mm. When the wiring board 13 and the lid 23 are bonded to each other in order to produce a package of electronic components, a second frame body 21 of the second assembly 2 to be described below and the first frame body 11 are overlapped so that the lid 23 is opposite to the wiring board 13 (see FIG. 7). Therefore, the total thickness of the wiring board 13 and the lid 23 may be approximately the same as the total thickness of the first frame body 11 and the second frame body 21. When the total thickness of the wiring board 13 and the lid 23 is substantially the same as the total thickness of the first frame body 11 and the second frame body 21, a gap is less likely to be formed between the wiring board 13 and the lid 23 when the first assembly 1 and the second assembly 2 are overlapped. As a result, the possibility that positional displacement occurs when the wiring board 13 and the lid 23 are bonded to each other can be reduced.

The first frame body 11 may include a plurality of positioning portions 119. The positioning portion 119 assists in determining the position of the wiring board 13 with respect to the first frame body 11 when the wiring boards 13 are arrayed. The positioning portion 119 may be constituted by, for example, a through hole, a notch, a recessed portion having a flat bottom surface, a mark, or the like. By using the positioning portion 119 as an index recognized by a camera or the like, the wiring board 13 can be arrayed at an accurate position when the wiring boards 13 are arrayed on the first sheet 12 of the first frame body 11. As illustrated in FIG. 1, when a plurality of the openings 11c arrayed in the wiring board 13 are provided, the positioning portion 119 may be provided for each opening 11c.

The first frame body 11 may include alignment portions 112, 113, 114, 115, 116, 117, and 118. These alignment portions assist the positioning of the first assembly 1 and the second assembly 2 when the assemblies are opposite to each other. Assuming that an upper side and a lower side in the Y-axis direction in FIG. 1 are an upper side and a lower side, respectively, the first frame body 11 may have the alignment portion 112 at a central portion of the upper side, the alignment portion 114 at a central portion of the lower side, and the alignment portion 113 obliquely above and to the right side of the alignment portion 112. That is, the first frame body 11 has alignment portions having different configurations on the upper side and the lower side. Each of the alignment portions 112, 113, and 114 may be constituted by, for example, a through hole, a notch, a hemispherical protruding portion, a mark, or the like. When the alignment portion is constituted by a protruding portion, an alignment portion to be described below of the second frame body 21 to be overlapped on the first frame body 11 is constituted as a hole having a shape and a depth corresponding to the protruding portion. In this case, no guide pins 61 are required in a bonding table 6 to be described below.

FIG. 1 illustrates a case where the alignment portions 112, 113, and 114 are through holes, the alignment portions 112 and 113 are circular in a plan view, and the diameter of the through hole of the alignment portion 113 is smaller than the diameter of the through hole of the alignment portion 112. The first frame body 11 may have the alignment portions 115, 116, 118, and 117 at four corners (counterclockwise from an upper left corner in FIG. 1), respectively. Each of the alignment portions 115, 116, 117, and 118 is constituted by, for example, a through hole, a notch, a hemispherical protruding portion, a mark, or the like. When the alignment portion is constituted by a protruding portion, an alignment portion to be described below of the second frame body 21 to be overlapped on the first frame body 11 is constituted as a hole having a shape and a depth corresponding to the protruding portion. In this case, no guide pins 61 are required in a bonding table 6 to be described below. In the example illustrated in FIG. 1, both the positioning portion and the alignment portion are provided; however, the alignment portion may also serve as the positioning portion.

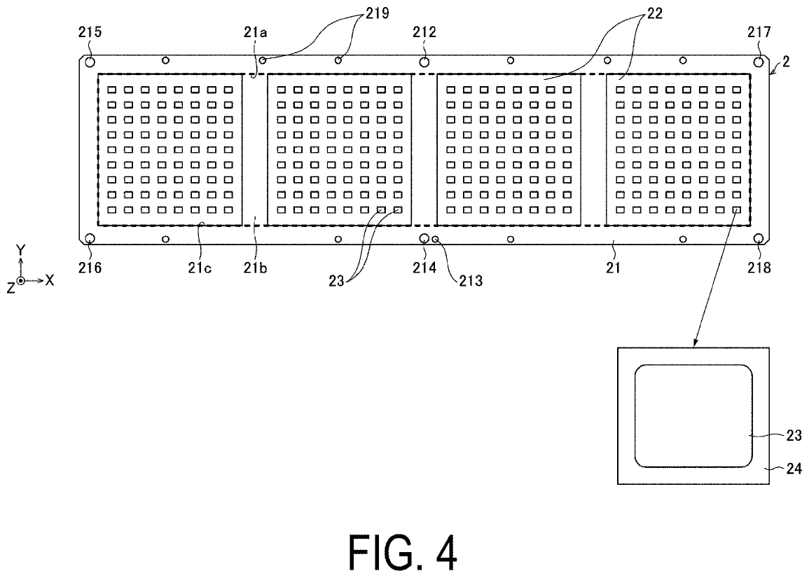

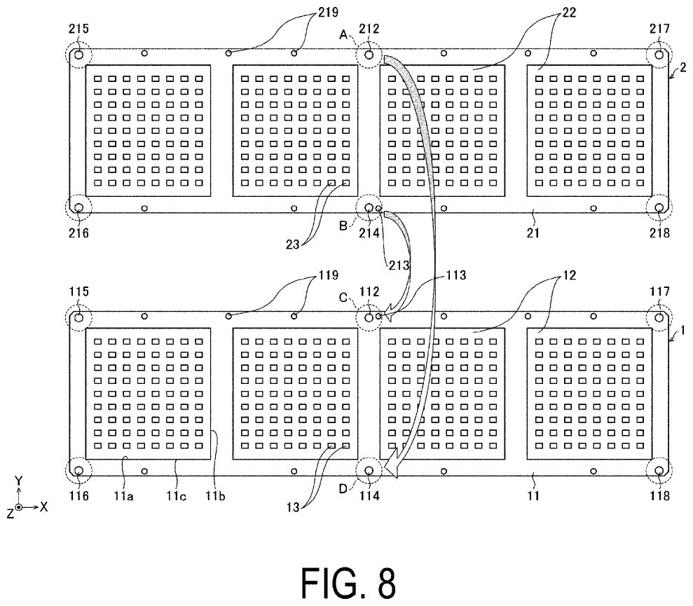

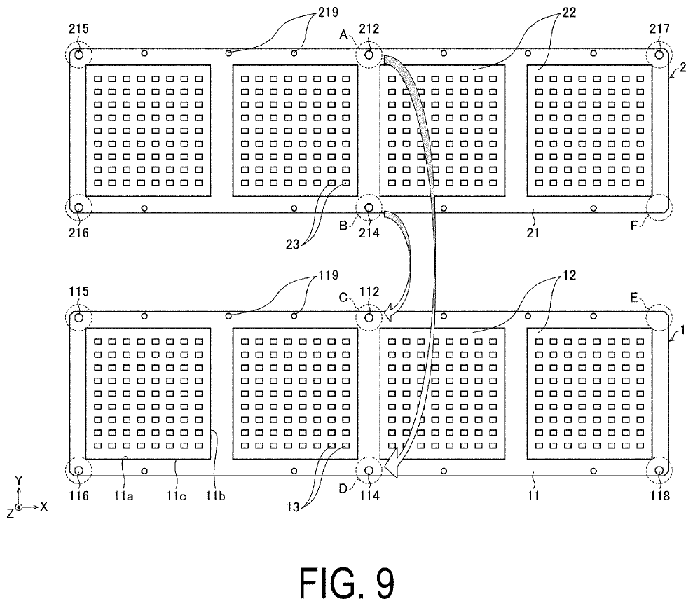

The alignment portion may also be provided to the second frame body 21 of the second assembly in the same manner as the first frame body 11 (see FIG. 4). The alignment portions 112 to 118 of the first frame body 11 and alignment portions 212 to 218 of the second frame body 21 are configured so that corresponding alignment portions are opposite to each other when the second assembly 2 (the second frame body 21) and the first assembly 1 are overlapped in a correct orientation. By adopting a configuration in which the positioning portions are not opposite to each other when an up-down direction, a left-right direction, and front and back sides are mistaken at the time of overlapping, errors in the overlapping can be reduced. The orientation or the like of the second frame body 21 may be confirmed by recognizing the arrangement of the alignment portions with a camera. A method for overlapping the first assembly 1 and the second assembly 2 will be described below (see FIGS. 8 and 9).

As another example of the example illustrated in FIG. 1, the first frame body 11 may have an alignment portion that is vertically asymmetric with respect to a line that passes through the center of the first frame body 11 and is parallel to the X-axis direction. For example, one of the corners may be cut out and used as the alignment portion, or a through hole that is vertically asymmetric, a through hole having a shape indicating directionality (such as a triangular shape having a specific orientation such as V), and a mark may be used as the alignment portion.

A bar code, a two-dimensional code, or the like may be attached to any portion of the first frame body 11 for LOT management or the like. The first frame body 11 may be reused.

### First Sheet

The first sheet 12 may be a sheet in which an adhesive such as a pressure-sensitive adhesive is attached to a base material. Since the wiring board 13 is peeled off from the first sheet 12 after being temporarily attached to the first sheet 12, the adhesive may be a pressure-sensitive adhesive. The adhesive may be attached to the base material by coating or the like from the beginning. In this case, the adhesive may be attached to the entire surface of the first sheet 12, or may be attached only to a portion where the wiring board 13 and the first frame body 11 are adhered to each other. At the time of manufacturing the electronic component, a manufacturer may attach the adhesive to the base material of the first sheet 12. From the viewpoint of handling and cost, the adhesive is preferably attached to one surface of the first sheet 12.

As the first sheet 12, for example, a polyimide (PI) sheet, an ultraviolet (UV) release sheet, a thermal release sheet, or the like can be used. The PI sheet is obtained by attaching a pressure-sensitive adhesive such as a silicone adhesive or an acrylic adhesive to a base material made of PI. The PI exhibits heat resistance to a temperature of, for example, 200° C., and when heated, the adhesive force easily increases, making it difficult to peel off. The UV release sheet is obtained by attaching a pressure-sensitive adhesive to a base material made of polyethylene terephthalate (PET). The UV release sheet is known as a dicing sheet used in a dicing step. Since UV can pass through the base material made of PET, when UV is radiated, the adhesive force is decreased, making it easier to peel off. The thermal release (heat foaming) sheet is a sheet whose adhesive force decreases when heated at a specific temperature or higher and which becomes easier to peel off. Since the first assembly 1 on which the wiring boards 13 are arrayed is heated at about 150° ° C. to 200° C. when electronic elements are mounted on the wiring boards 13, the PI sheet having heat resistance may be used as the first sheet 12. When the thermal release sheet is used, the specific temperature at which peeling becomes easy may be higher than the heating temperature at the time of mounting, for example, 210° C. or higher. In the first assembly 1, the first frame body 11 and the wiring board 13 may be disposed on the same surface of the first sheet 12, or may be disposed on opposite sides of the first sheet 12. In a case where the first frame body 11 and the wiring board 13 are disposed on the same surface of the first sheet 12, since no gap is formed between the first sheet 12 and the bonding table 6 when the first frame body 11 and the wiring board 13 are placed on the bonding table 6 in the sealing step, the first sheet 12 can be pressed from the upper side without being deformed (see FIG. 7). Even at the time of mounting, the first assembly 1 can be heated by a heater built in the bonding table 6. At the time of die bonding or wire bonding, the first sheet 12 can be sucked through a through hole (not illustrated) provided in the bonding table 6 to stabilize the wiring board 13.

The first sheet 12 is adhered to close the first frame body 11. From the viewpoint of strength, four sides of the opening 11c having a rectangular shape are preferably adhered. When a plurality of the openings 11c are provided, a plurality of first sheets 12 may be used to close the openings 11c individually, or one first sheet 12 may be used to close all the plurality of openings 11c.

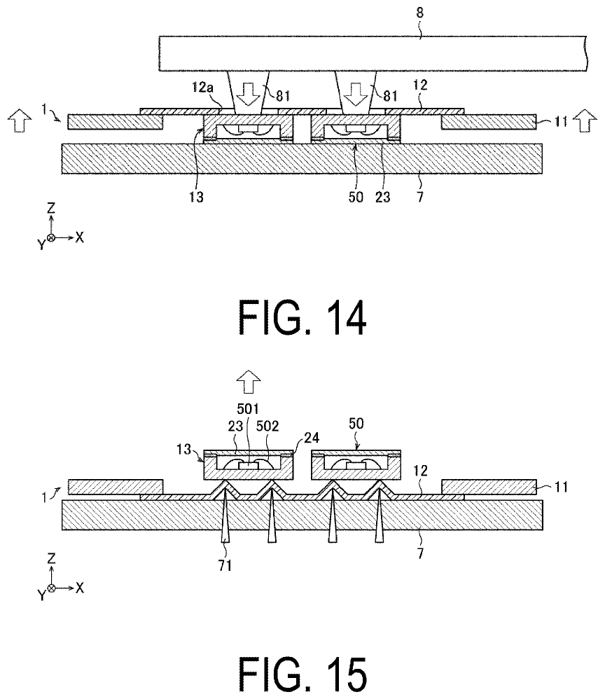

The first sheet 12 may have a hole 12a to be described below at a position corresponding to the wiring board 13 (see FIG. 14). An outer edge of the hole 12a may be located inside an outer edge of the wiring board 13 in a plan view. In other words, the area of the hole 12a is smaller than the adhesive area of the wiring board 13 on the first sheet 12. Laser marking can be performed on the back surface of an insulating board 131 of the wiring board 13 through the hole 12a. The hole 12a can be used when the first sheet 12 is peeled off from the insulating board 131. The use of the hole 12a will be described below. When the wiring board is a board having a through hole as in a board for a MEMS microphone, the first sheet 12 having the hole 12a at a position corresponding to the through hole is particularly advantageous. By using the first sheet 12 having the hole 12a, the hole 12a serves as an air vent hole. This can reduce the possibility that air in a sealed MEMS microphone element expands when heated, so the element is peeled off or damaged.

### Wiring Board

For example, as in the example illustrated in FIG. 2, the wiring board 13 includes the insulating board 131 having a recessed portion on an upper surface thereof and the wiring conductor 132 provided from a bottom surface of the recessed portion to a lower surface of the insulating board 131. The insulation board 131 has a rectangular shape in a plan view, and can use, for example, a ceramic such as an aluminum oxide sintered body (alumina ceramic), an aluminum nitride sintered body, a silicon nitride sintered body, a mullite sintered body, or a glass ceramic sintered body. The wiring conductor 132 includes an electrode located on the bottom surface of the recessed portion, an external terminal located on the lower surface of the insulating board 131, and an internal wiring located inside the insulating board 131 and connecting the electrode and the external terminal. The wiring board 13 may have a step portion in the recessed portion and may have an electrode on the step portion. An electronic element is mounted on the bottom surface of the recessed portion. Each wiring board 13 is cut out by snap breaking, dicing, laser, or the like from a mother board (multi-piece board) of the wiring board 13 in which the wiring conductors 132 and recessed portions corresponding to the plurality of wiring boards 13 are provided on a base material, so that the wiring boards 13 are singulated. The plurality of singulated wiring boards 13 are adhered to the first sheet 12 at predetermined intervals. Examples of the distance between the arrayed wiring boards 13 include 0.1 mm to 1 mm. The wiring boards 13 are arrayed and adhered to the first sheet 12 by a mounting device capable of highly accurate positioning by camera recognition or the like, for example. The wiring board 13 is adhered to the first sheet 12 after the singulation. Therefore, a wiring board 13, which is inspected after the singulation and determined to be a non-defective product or the like, can be adhered to the first sheet 12.

In the first assembly 1, the wiring boards 13 are arrayed with high positional accuracy and adhered to the first sheet 12. In a wiring board assembly in the related art in which a plurality of wiring boards are integrally formed, that is, a multi-piece ceramic board, a dimensional variation occurs due to a firing shrinkage variation of about 0.1% to 1%. Therefore, in an assembly of wiring boards of about 100 mm square, a variation in the position of each wiring board may occur by about 100 μm to 1000 μm. On the other hand, the wiring boards 13 adhered to the first sheet 12 after the singulation can be arrayed on the first assembly 1 with a positional accuracy of 100 μm or less by a high-accuracy mounting device.

According to the first assembly 1, an electronic component in which an electronic element is sealed can be manufactured by mounting the electronic element on the wiring board 13 and then bonding the lid 23 to the wiring board 13 on a one to-one basis or covering the electronic element with a sealing resin. Since the singulated wiring boards 13 are adhered to the first sheet 12 and the positional accuracy of each wiring board 13 in the first assembly 1 is high, the mounting of the electronic element on each wiring board 13 and the bonding of the lid 23 are performed with high accuracy. Therefore, electronic component having excellent reliability can be manufactured. Since the first assembly 1 in which the plurality of wiring boards 13 are arrayed is used, the production efficiency of electronic components is high as compared with when electronic components are manufactured one by one. When the plurality of wiring boards 13 are individually sealed, the wiring boards 13 can be peeled off from the first sheet 12 after the electronic elements are sealed, so that the wiring boards 13 can be singulated without a cutting operation such as dicing. The absence of the cutting process can shorten the manufacturing time. When materials of the wiring board 13 and the lid 23 are different from each other, no highly accurate cutting may be possible and the sealing property may be lowered. Since the lid 23 is bonded by highly accurate positioning to the singulated wiring boards 13 arrayed with high accuracy, the sealing property of all the wiring boards 13 can be secured. Since the shape of the first frame body 11 can be freely designed, the size of the first frame body 11 (first assembly 1), the size of the first sheet 12, and the array of the wiring boards 13 in the first sheet 12 can be set in accordance with an electronic element mounting device. This improves the working efficiency of the sealing step.

### Second Assembly (Lid Assembly)

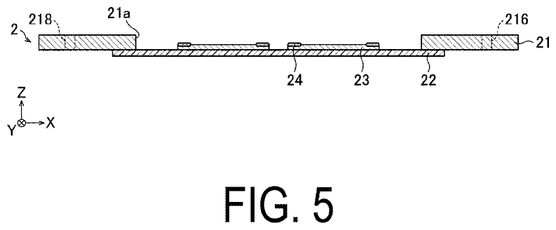

FIG. 4 is a plan view illustrating the second assembly 2. FIG. 5 is a cross-sectional view illustrating the second assembly 2. The second assembly 2 includes a second frame body 21 having a rectangular shape, a second sheet 22 closing the second frame body 21, and a plurality of lids 23 adhered to one surface of the second sheet 22.

### Second Frame Body

The second frame body 21 has the same configuration as the first frame body 11. The second frame body 21 has an opening 21a, and has three beams 21b that bridge the periphery of the opening 21a in the Y-axis direction and are arranged at substantially equal intervals along the X-axis direction. The opening 21a is divided into four openings 21c by the beams 21b. Assuming that an upper side and a lower side of the second frame body 21 in the Y-axis direction in FIG. 4 are an upper side and a lower side, respectively, the second frame body 21 has a plurality of positioning portions 219 used when the lids 23 are arrayed on the upper side and the lower side. The positioning portion 219 is provided to be recognized by a camera, and is constituted by, for example, a through hole, a notch, a recessed portion having a flat bottom surface, a mark, or the like. As illustrated in FIG. 4, when a plurality of the openings 21c in which the lids 23 are arrayed is provided, the positioning portion 219 may be provided for each opening 21c.

In order to align the first assembly 1 and the second assembly 2 with each other, the second frame body 21 may have the alignment portion 212 at a central portion of the upper side, the alignment portion 214 at a central portion of the lower side, and the alignment portion 213 obliquely above and to the right side of the alignment portion 214. Each of the alignment portions 212, 213, and 214 may be constituted by, for example, a through hole, a notch, a hemispherical protruding portion, a mark, or the like. When the alignment portion is constituted by a protruding portion, an alignment portion of the first frame body 11 overlapping the second frame body 21 is constituted as a hole having a shape and a depth corresponding to the protruding portion. In this case, no guide pins 61 are required in a bonding table 6 to be described below.

FIG. 4 illustrates a case where the alignment portion is a through hole. In this case, the alignment portions 214 and 213 are circular in a plan view, and the diameter of the through hole of the alignment portion 213 is smaller than the diameter of the through hole of the alignment portion 214. The second frame body 21 may have alignment portions 215, 216, 218, and 217 at four corners (counterclockwise from an upper left corner in FIG. 4), respectively. Each of the alignment portions 215, 216, 217, and 218 is constituted by, for example, a through hole, a notch, a hemispherical protruding portion, a mark, or the like. When the alignment portion is constituted by a protruding portion, an alignment portion of the first frame body 11 overlapping the second frame body 21 is constituted as a hole having a shape and a depth corresponding to the protruding portion. In this case, no guide pins 61 are required in a bonding table 6 to be described below.

When the second assembly 2 (the second frame body 21) is overlapped on the first assembly 1, positioning portions are opposite to each other, and when the reverse direction (the up-down direction or the left-right direction) is mistaken, the positioning portions are not opposite to each other, so that errors in the overlapping can be reduced. The orientation or the like of the second frame body 21 may be confirmed by recognizing the arrangement of the alignment portions with a camera.

In order to recognize the up-down direction of the second frame body 21, the second frame body 21 may have an alignment portion that is vertically asymmetric with respect to a line that passes through the center of the second frame body 21 and is parallel to the X-axis direction. For example, one of the corners may be cut out and used as the alignment portion, or a through hole that is vertically asymmetric, a through hole having a shape indicating directionality (such as a triangular shape having a specific orientation such as V), and a mark may be used as the alignment portion. In order to recognize the left-right direction of the second frame body 21, the second frame body 21 may have an alignment portion that is bilaterally asymmetric with respect to a line that passes through the center of the second frame body 21 and is parallel to the Y-axis direction. The second frame body 21 may also have a protruding portion or a mark for indicating the up-down direction or the left-right direction on the back surface (surface on which the lid 23 is not exposed from the opening 21c).

A bar code, a two dimensional code, or the like may be attached to any portion of the second frame body 21 for LOT management or the like. The second frame body 21 may be reused.

### Second Sheet

The second sheet 22 has the same configuration as the first sheet 12. Since the second assembly 2 is not exposed to a high temperature at the time of chip mounting and requires no heat resistance like the first sheet 12, a UV release sheet or a thermal release sheet can be used.

### Lid

The lid 23 may have, for example, a rectangular shape in a plan view. The lid 23 can use, for example, a ceramic such as an aluminum oxide sintered body (alumina ceramic), an aluminum nitride sintered body, a silicon nitride sintered body, a mullite sintered body, or a glass ceramic sintered body, Si, Ge, a glass material, or a metal material such as a FeNiCo alloy or a FeNi alloy. When the lid 23 is made of ceramic, for example, each lid 23 can be cut out from a base material by snap breaking, dicing, laser, or the like to be singulated. The lid 23 may be a ceramic plate produced one by one (as an individual piece) by press molding without being cut out, or a metal plate produced in an individual piece shape by pressing (die punching). The plurality of singulated lid bodies 23 are adhered to the second sheet 22 so as to correspond to the arrangement of the wiring boards 13 on the first sheet 12. The lid 23 disposed on the second sheet 22 may be a selected lid 23 such as a non-defective product. The lid 23 has a sealing material 24 including a synthetic resin such as an epoxy resin at a peripheral edge of a surface facing the wiring board 13. The sealing material 24 may be solder. In the case of solder, a base metal to which solder is bonded may be provided at a predetermined position of the lid 23 or the wiring board 13. The sealing material 24 may be attached to the peripheral edge of the wiring board 13 instead of the lid 23.

The lid 23 is not limited to a flat plate shape as in the example illustrated in FIG. 5, and may have, for example, a cup shape to be described below. When an electronic element mounted on the wiring board 13 is an optical element to be described below, the lid 23 may have a window portion for transmitting light. The window portion is formed by closing an opening of a main body of the lid 23 with a light-transmissive member, and the light-transmissive member may be a glass plate having a flat plate shape or a lens. The light-transmissive member may include an optical film such as an antireflection film or an optical filter film. As will be described below, the lid 23 may have a wiring or an external terminal.

According to the second assembly 2, electronic components can be manufactured by mounting electronic elements on the plurality of wiring boards 13 and then bonding the plurality of lids 23 to the plurality of wiring boards 13 in one time.

### Package Set

The package set 3 includes the first assembly 1 and the second assembly 2, and the plurality of lids 23 are located on one surface of the second sheet 22 so as to correspond to the plurality of wiring boards 13.

According to the package set 3, after electronic elements are mounted on the plurality of wiring boards 13, the plurality of lid bodies 23 can be collectively bonded to the plurality of wiring boards 13 to manufacture electronic components, resulting in good productivity. The lid 23 is arranged at a position corresponding to the wiring board 13, and the assemblies arrayed with high accuracy by the above camera recognition are overlapped with each other instead of a mother board state having a dimensional error, so that positional accuracy is high and sealing reliability is high. That is, the arrangement (adhesion) of the wiring board 13 on the first sheet 12 and the arrangement (adhesion) of the lid 23 on the second sheet 22 can be performed with reference to positioning portions of the same arrangement (recognized by the camera). Each arrangement can be performed by the same mounting device. Accordingly, the correspondence accuracy between the position of the wiring board 13 and the position of the lid 23 is high. The wiring board 13 and the lid 23 may be mounted by recognizing holes at the same position in the first frame body 11 and the second frame body 21 processed by the same mold.

### Method for Manufacturing Electronic Component

The method for manufacturing an electronic component will be described below.

### First Manufacturing Method

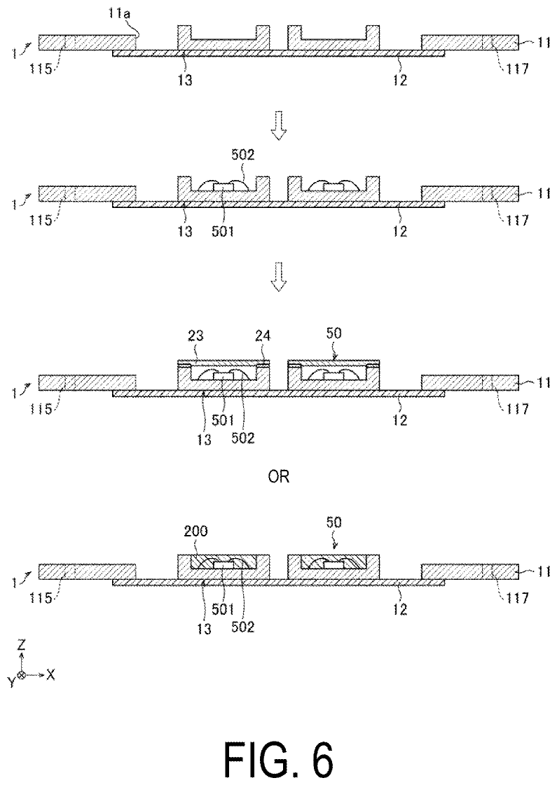

An electronic component 50 can be manufactured by the following first manufacturing method. FIG. 6 is a cross-sectional view illustrating the first manufacturing method of the electronic component 50.
(1) The first assembly 1 is prepared.
(2) An electronic element 501 is mounted on each of the plurality of wiring boards 13 of the first assembly 1, and an electrode of the electronic element 501 and an electrode of the wiring board 13 are connected by a wire 502.
(3) The individual lid 23 is bonded to each wiring board 13 to seal the electronic element 501, so that the electronic component 50 is obtained. The electronic component 50 is obtained by covering the electronic element 501 with a resin 200 to seal the electronic element 501.
(4) The electronic component 50 (wiring board 13) is peeled off from the first sheet 12.

The first manufacturing method uses the first assembly 1 in which the individual wiring boards 13 are arrayed with high positional accuracy. Therefore, the electronic element 501 can be mounted on the wiring board 13 with high positional accuracy, and the lid 23 can be bonded to the wiring board 13 with high positional accuracy. After the plurality of electronic elements 501 are individually sealed, cutting after sealing is not necessary, and thus the electronic component 50 can be manufactured with high productivity. When the material of the wiring board 13 is different from the material of the lid 23, the wiring board 13 and the lid 23 may not be cut with high accuracy, which may reduce the sealing property. On the other hand, according to the first manufacturing method, since the lid 23 can be bonded by highly accurate positioning to the singulated wiring boards 13 arrayed with high positional accuracy, the reliability of sealing can be improved.

The electronic element 501 is not limited to the MEMS microphone element described above. For example, an electronic element 501 corresponding to the electronic component 50 to be manufactured, such as a piezoelectric element such as a quartz crystal resonator or a surface acoustic wave (SAW) element, an optical element such as a light emitting element, a light receiving element, or an imaging element, a sensor element such as an acceleration sensor, or a semiconductor integrated circuit element such as an integrated circuit (IC) element, can be mounted on the wiring board 13.

### Second Manufacturing Method

An electronic component 50 can be manufactured by the following second manufacturing method. FIG. 7 is a cross-sectional view illustrating the second manufacturing method of the electronic component.
(1) As illustrated in FIG. 7, the first assembly 1 and the second assembly 2 are prepared. The package set 3 described above can be used. The second assembly 2 is used with a surface of the second sheet 22 having the lid 23 facing downward (turned upside down). The first assembly 1 may be manufactured by adhering the first sheet 12 to the first frame body 11 having the opening 11a so as to close the opening 11a, and arranging the plurality of wiring boards 13 on the first sheet 12. The second assembly 2 may be manufactured by adhering the second sheet 22 to the second frame body 21 having the opening 21a so as to close the opening 21a and arranging the plurality of lids 23 on the second sheet 22.

In FIG. 7, the first frame body 11 and the wiring board 13 are located on the same surface of the first sheet 12 in the first assembly 1, and the second frame body 21 and the lid 23 are located on the same surface of the second sheet 22 in the second assembly 2. An adhesive may be present on only one surface of the sheet. The wiring board 13 or the lid 23 and the first frame body 11 or the second frame body 21 can be adhered by one adhesive. Since the member is surrounded by the first frame body 11 or the second frame body 21, the amount of protruding of the member is reduced and the member is protected. The surface of the first sheet 12 to which the first frame body 11 and the wiring board 13 of the first assembly 1 are adhered and the surface of the second sheet 22 to which the second frame body 21 and the lid 23 of the second assembly 2 are opposite to each other, so that the wiring board 13 and the lid 23 can be bonded to each other.

FIG. 7 illustrates a case where the package set 3 is used. Since the plurality of lids 23 are located on one surface of the second sheet 22 so as to correspond to the plurality of wiring boards 13, the lid 23 can be overlapped on the wiring board 13 by allowing the surface of the first assembly 1 on the wiring board 13 side to be opposite to the surface of the second assembly 2 on the lid 23 side. The method for overlapping will be described below.
(2) The electronic element 501 is mounted on each of the plurality of wiring boards 13 of the first assembly 1, and the electrode of the electronic element 501 and the electrode (bonding pad) of the wiring board 13 are connected by the wire 502. The electrodes may be connected by flip-chip bonding.
(3) The first assembly 1 and the second assembly 2 are overlapped so that the plurality of wiring boards 13 on which the electronic elements 501 are mounted and the plurality of lids 23 of the second assembly 2 are opposite to each other. At this time, the bonding table 6 having a plurality of guide pins 61 may be used as illustrated in FIG. 7. The guide pins 61 of the bonding table 6 are inserted into the alignment portion 115 that is a hole of the first frame body 11 and the alignment portion 216 that is a hole of the second frame body 21, respectively. The other guide pins 61 of the bonding table 6 are inserted into the alignment portion 117 that is a hole of the first frame body 11 and the alignment portion 218 that is a hole of the second frame body 21, respectively. Thus, the wiring board 13 and the lid 23 can be aligned. The alignment portions of the first assembly 1 and the second assembly 2 may be recognized by a camera, or the wiring board 13 of the first assembly 1 and the lid 23 of the second assembly 2 may be recognized by a camera, thereby achieving alignment.
(4) The plurality of lids 23 are bonded to the plurality of wiring boards 13 by the sealing material 24 to seal the electronic elements 501. By heating at 120° C. while applying a load of, for example, 1 kgf/cm² from the second sheet 22 side, the lid 23 is bonded to the wiring board 13 by the sealing material 24 and the electronic elements 501 are sealed, so that the electronic component 50 is obtained.
(5) The portion of the electronic component 50 on the wiring board 13 side is peeled off from the first sheet 12.
(6) The portion of the electronic component 50 on the lid 23 side is peeled off from the second sheet 22.

According to the second manufacturing method, the electronic component 50 can be manufactured by mounting electronic elements on the plurality of wiring boards 13 and then collectively bonding the plurality of lid bodies 23 to the plurality of wiring boards 13, resulting in good productivity. The lid 23 is arrayed at a position corresponding to the wiring board 13, so that positional accuracy is high and sealing reliability is high. Since the lid is handled as an individual piece in the first manufacturing method, productivity is higher in the second manufacturing method in which collective sealing is performed in a state in which the lid 23 is also adhered to the second sheet 22. In the second manufacturing method, after the plurality of wiring boards 13 are peeled off from the first sheet 12, the plurality of lid bodies 23 are peeled off from the second sheet 22, but the order may be reversed.

### Method for Overlapping First Assembly and Second Assembly

FIG. 8 is an explanatory view for explaining a method for overlapping the first assembly 1 and the second assembly 2. In FIG. 8, the X-axis direction is a left-right direction, and the Y-axis direction is an up-down direction. The first frame body 11 of the first assembly 1 includes the alignment portion 113 located obliquely above and to the right side of the alignment portion 112, and the shape of the first frame body 11 is asymmetric in the up-down direction and the left-right direction due to the overall arrangement of the alignment portions 112 to 118. The second assembly 2 includes the alignment portion 213 located obliquely above and to the right side of the alignment portion 214, and the shape of the second frame body 21 is asymmetric in the up-down direction and the left-right direction due to the overall arrangement of the alignment portions 212 to 218. As illustrated in FIG. 8, the first assembly 1 is placed on a placement table (not illustrated) so that the alignment portions 112 and 113 (hereinafter, referred to as a portion C) are located on the upper side. The second assembly 2 is placed on the placement table on the upper side of the first assembly 1 in the Z-axis direction in a state where the alignment portion 212 (hereinafter, referred to as a portion A) is located on the upper side in the Y-axis direction. The second assembly 2 is turned upside down and placed on the first assembly 1 so that the portion A of the second assembly 2 overlaps the alignment portion 114 (hereinafter, referred to as a portion D) of the first assembly 1 and the alignment portions 214 and 213 (hereinafter, referred to as a portion B) of the second assembly 2 overlap the portion C of the first assembly 1. When the alignment portions are correctly overlapped, 113 of the portion C and 213 of the portion B are overlapped and communicate with each other, so that the pins can pass through and the alignment portions are confirmed to be correct. It may be determined whether the overlapping method is correct by confirming that the front and back sides are optically connected to each other by a light emitting element, a light receiving element, camera recognition, or the like. By doing so, the placement directions of the first assembly 1 and the second assembly 2 are confirmed to be correct and the rotation direction of the second assembly 2 is confirmed to be correct.

When the second assembly 2 is placed upside down (rotated by 180° in an XY plane direction) on the placement table and is turned upside down to be overlapped on the first assembly 1, the portion A of the second assembly 2 is opposite to the portion C of the first assembly 1 and the portion B of the second assembly 2 is opposite to the portion D of the first assembly 1. In this case, since 113 of the portion C and 213 of the portion B do not overlap each other and no pin or light passes through, the overlapping method is confirmed to be incorrect. By aligning the positions of the first assembly 1 and the second assembly 2 with each other by the alignment portions, the lid 23 and the wiring board 13 can be properly aligned with each other.

Although the case where the second assembly 2 is turned upside down and overlapped on the first assembly 1 has been described above, the second assembly 2 may be turned right and left and overlapped on the first assembly 1. Also in this case, alignment portions are provided so that holes of the alignment portions can be confirmed to be overlapped to communicate with each other when the second assembly 2 is correctly overlapped on the first assembly 1.

FIG. 9 is an explanatory view for explaining a method for overlapping the first assembly 1 and the second assembly 2. Unlike FIG. 8, the first frame body 11 of the first assembly 1 has no alignment portion at an upper right corner (hereinafter, referred to as a portion E), and the second frame body 21 of the second assembly 2 has no alignment portion at a lower right corner (hereinafter, referred to as a portion F). The first frame body 11 does not have the alignment portion 113, and the second frame body 21 does not have the alignment portion 213. As illustrated in FIG. 9, the first assembly 1 is placed on the placement table so that the portion C is located on the upper side. The second assembly 2 is placed on the placement table in a state where the portion A is located on the upper side of the first assembly 1. The second assembly 2 is turned upside down so that the portion A of the second assembly 2 overlaps the portion D of the first assembly 1 and the portion B of the second assembly 2 overlaps the portion C of the first assembly 1, and is overlapped on the upper side of the first assembly 1 in the Z-axis direction. At this time, the portion E of the first assembly 1 and the portion F of the second assembly 2 overlap each other. That is, when the placement direction of the second assembly 2 is correct, the holes communicate with each other between the portion A and the portion D and between the portion B and the portion C. The alignment portions 215 and 116 overlap each other, the alignment portions 216 and 115 overlap each other, and the alignment portions 217 and 118 overlap each other. Pins or light can pass through the communicating holes, and the method for overlapping is determined to be correct.

When the second assembly 2 is placed upside down (rotated by 180° in an XY plane direction) on the placement table and is turned upside down to be overlapped on the first assembly 1, the portion A of the second assembly 2 is opposite to the portion C of the first assembly 1 and the portion B of the second assembly 2 is opposite to the portion D of the first assembly 1. The portion F having no alignment portion of the second assembly 2 is opposite to the alignment portion 116 of the first assembly 1, and the alignment portion 116 is closed by the portion F. The alignment portion 215 of the second assembly 2 is opposite to the portion E having no alignment portion of the first assembly 1, and the alignment portion 215 is closed by the portion E. Since the alignment portions 217 and 118 do not overlap each other, no holes communicate with each other and no pin or light is not able to pass through, so that the method for overlapping is determined to be incorrect. When the second assembly 2 is turned right and left and placed on the first assembly 1, the second assembly 2 is turned upside down and placed on the placement table in the same method for overlapping as when the second assembly 2 is turned upside down, so that the method for overlapping is determined to be incorrect.

Type of First Sheet and Second Sheet and Order of Peeling of Electronic Component from Sheet

Hereinafter, the type of the first sheet and the second sheet of the package set and the order of peeling off the first sheet and the second sheet at the time of manufacturing the electronic component will be described.

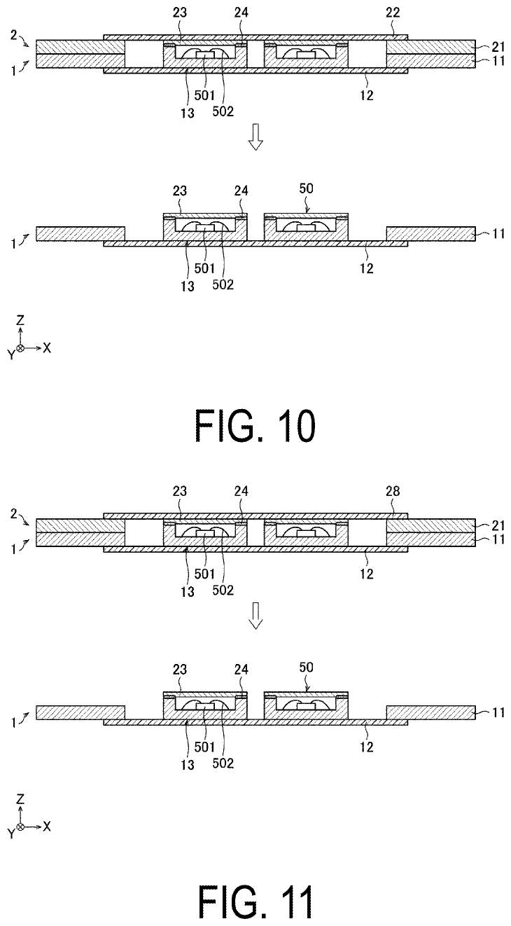

FIG. 10 is a cross-sectional view illustrating an example of a method for manufacturing the electronic component 50. In FIG. 10, both the first sheet 12 and the second sheet 22 are PI sheets, and the adhesive strength of the first sheet 12 is higher than the adhesive strength of the second sheet 22. As described in FIG. 7, the plurality of lids 23 are bonded to the plurality of wiring boards 13 by the sealing material 24 to seal the electronic elements 501, so that the electronic components 50 are obtained.

As illustrated in FIG. 10, the second sheet 22 is peeled off from the electronic components 50 (lid 23). In a case where the first sheet 12 and the second sheet 22 have the same adhesive strength, when the second sheet 22 is peeled off first, some electronic components 50 may remain on the first sheet 12 and some electronic components 50 may remain on the second sheet 22. By using sheets having different adhesive strengths in the first assembly 1 and the second assembly 2, all the electronic components 50 remain on the first sheet 12 side, resulting in good productivity.

When sealing is performed at a sealing temperature lower than the mounting temperature of the electronic components, a UV sheet that is easily peeled off may be used as the second sheet 22 in the second assembly 2. After an electronic element is sealed, the second sheet 22 can be easily peeled off by radiating UV.

FIG. 11 is a cross-sectional view illustrating an example of a method for manufacturing the electronic component 50. In the first assembly 1, a PI sheet having high heat resistance may be used as the first sheet 12. In the second assembly 2 in which sealing is performed at a sealing temperature of about 150° C., which is lower than the mounting temperature of the electronic component 50, a thermal release sheet that thermally releases at 150° C. may be used as a second sheet 28. After the electronic element 501 is sealed, since the second sheet 28 is automatically peeled off, a step for peeling off the second sheet 28 by radiating UV or the like is omitted.

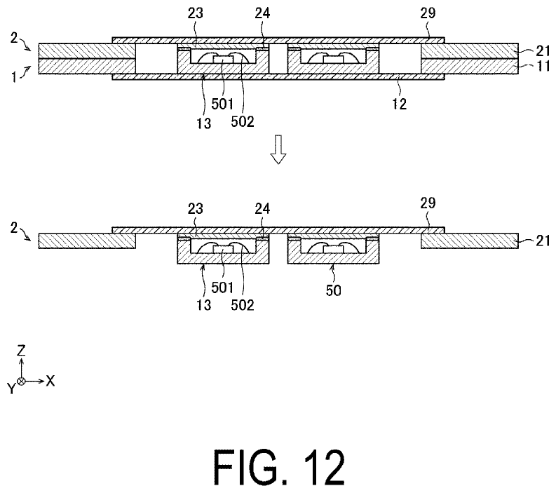

FIG. 12 is a cross-sectional view illustrating an example of a method for manufacturing the electronic component 50. In the first assembly 1, a PI sheet having high heat resistance may be used as the first sheet 12. In the second assembly 2, a UV release sheet having a higher adhesive strength than the first sheet 12 may be used as a second sheet 29. Only the first sheet 12 having a low adhesive strength can be peeled off first. Subsequently, the second sheet 29 can be easily peeled off by radiating UV. A thermal release sheet having a higher adhesive strength than the first sheet 12 may also be used as the second sheet 29. Also in this case, the second sheet 29 can be easily peeled off by heating after only the first sheet 12 is peeled off first. In this way, by using the second sheet 29 that has a higher adhesive strength than the first sheet 12 and can be peeled off by post-processing such as radiating UV or heating, the electronic component 50 can be peeled off sequentially from the first sheet 12 and the second sheet 29. When the first sheet 12 and the second sheet 29 are peeled off from the electronic component 50, the stress applied to the electronic component 50 can be reduced, thereby reducing the possibility that the sealing property is lowered or the mounting reliability of the electronic element 501 is lowered due to the stress.

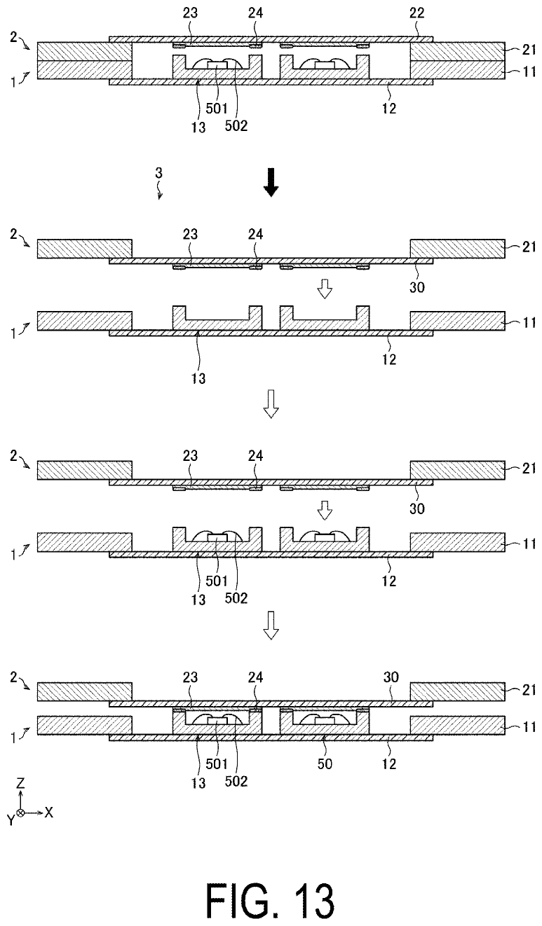

FIG. 13 is a cross-sectional view illustrating an example of a method for manufacturing the electronic component. As illustrated in the uppermost drawing of FIG. 13, when the lid 23 is thinner than the second frame body 21 and both the second frame body 21 and the lid 23 are adhered to one surface of the second sheet 22, a gap is formed between the lid 23 and the wiring board 13 when the first frame body 11 and the second frame body 21 are overlapped and the lid 23 is opposite to the wiring board 13, resulting in a difficulty in bonding the lid 23 to the wiring board 13. Due to pressurization at the time of bonding, the second sheet 22 may be bent and the position of the lid 23 may be displaced. On the other hand, as illustrated in the drawings below the black arrow in FIG. 13, the package set 3 may be used in which a double-sided adhesive sheet is used as the second sheet 30, one surface of a second sheet 30 is adhered to the second frame body 21, and then the lid 23 is adhered to the other surface of the second sheet 30. By doing so, when the second assembly 2 is overlapped on the first assembly 1, the difference in thickness between the second frame body 21 and the lid 23 is eliminated, so that the lid 23 can be overlapped on the wiring board 13. Therefore, the possibility of occurrence of positional displacement can be reduced.

The second sheet 22 of the second assembly 2 is not limited to be a double-sided adhesive sheet, and the first sheet 12 of the first assembly 1 may be a double-sided adhesive sheet. The first sheet 12 may be a double-sided adhesive sheet in addition to the second sheet 22. Since the first sheet 12 is in contact with the placement table, the first sheet 12 can be heated by a heater of the placement table and only the second sheet 22 may be a double-sided adhesive sheet from the viewpoint that the first sheet 12 is not deformed at the time of pressurization.

### Method for Peeling Electronic Component

Hereinafter, a method for peeling an electronic component will be described.

FIG. 14 is a cross-sectional view illustrating a state where the first sheet 12 is peeled off from the electronic component 50. The first sheet 12 has the hole 12a at a position corresponding to the wiring board 13. The area of the hole 12a is smaller than the area of the insulating board 131 of the wiring board 13, and the adhesive region of the wiring board 13 is secured. After the second sheet 22 is peeled off from the lid 23, the first assembly 1 is turned over and placed on a placement table 7. For example, a truncated cone-shaped protruding portion 81 of a jig 8 is inserted into the hole 12a, the electronic component 50 is fixed by pressing the wiring board 13, and the first frame body 11 is raised to peel off the first sheet 12 from the wiring board 13. The first sheet 12 is easily peeled off from the wiring board 13. The placement table 7 may have a recessed portion into which the electronic component 50 is inserted, and the electronic component 50 may be pressed by the protruding portion 81 of the jig 8 to be peeled off toward a bottom surface of the recessed portion in a state where the first frame body 11 is supported by a peripheral edge of the recessed portion.

FIG. 15 is a cross-sectional view illustrating a state where the electronic component 50 is peeled off from the first sheet 12. After the second sheet 22 is peeled off from the lid 23, the first sheet 12 on which the electronic component 50 remains is placed on the placement table 7. A plurality of pins 71 are vertically and movably inserted through the placement table 7. In a state where the pin 71 is moved upward to push up the electronic component 50 and an adhesive area is reduced, the electronic component 50 can be peeled off by sucking the electronic component 50 from above or chucking the electronic component 50.

Peeling of First Sheet from First Frame Body

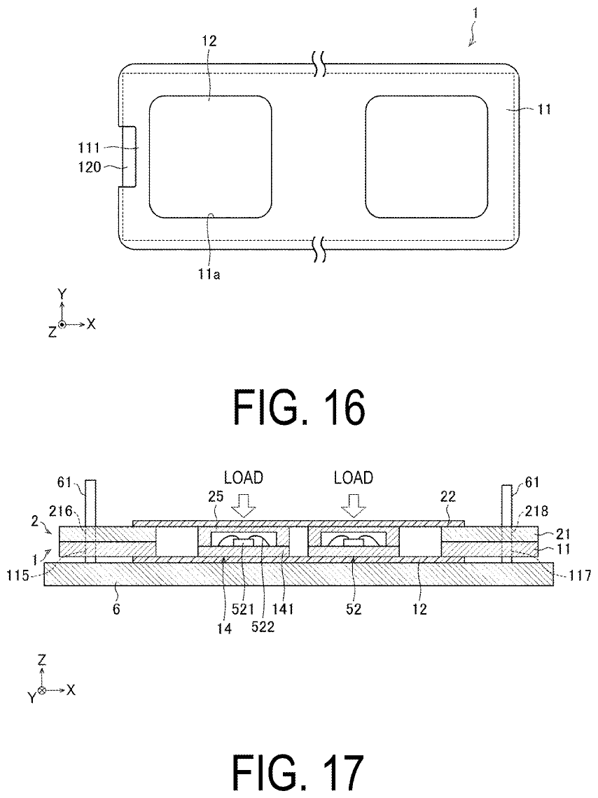

FIG. 16 is a plan view illustrating the first assembly 1 in a state where the wiring board 13 is peeled off from the first sheet 12. As illustrated in FIG. 16, the first frame body 11 has a notch 111 at a central portion of a side extending in the Y-axis direction illustrated in FIG. 16. Due to the notch 111, a part of the peripheral edge of the first sheet 12 is exposed as an exposed portion 120. After the wiring board 13 is peeled off from the first sheet 12 at the time of manufacturing the electronic component, the first sheet 12 needs to be finally removed from the first frame body 11; however, for example, when the entire peripheral edge of the first sheet 12 is adhered to the first frame body 11, it is difficult to peel off the first sheet 12. When the peripheral edge of the first frame body 11 has the notch 111 from which the peripheral edge of the first sheet 12 is exposed, the first sheet 12 can be easily peeled off by gripping the exposed portion 120 of the first sheet 12 exposed from the notch 111.

The first frame body 11 may have a through hole in the vicinity of the edge of the first frame body 11 instead of the notch 111. When the first frame body 11 has the notch 111, since the exposed portion 120 of the first sheet 12 is exposed and an end portion of the first sheet 12 is located in the notch 111, the peripheral edge of the first sheet 12 is easily gripped even without a jig or the like for pushing the first sheet 12. When the first frame body 11 has a through hole, the end portion of the first sheet 12 may not be exposed (the entire through hole may be covered by the first sheet 12); however, when the first sheet 12 is pressed through the through hole, the end portion of the first sheet 12 is turned up and the first sheet 12 is easily peeled off. In the case of the through hole, the end portion of the first sheet 12 is preferably exposed in the through hole.

The second frame body 21 may have a notch or a through hole (not illustrated) at a central portion of a side extending in the Y-axis direction illustrated in FIG. 5 to expose a part of the peripheral edge of the second sheet 22. When the peripheral edge of the second frame body 21 has a notch from which the peripheral edge of the second sheet 22 is exposed, the second sheet 22 can be easily peeled off by gripping the peripheral edge of the second sheet 22 exposed from the notch.

### Variation of Electronic Component

FIG. 17 is a cross-sectional view illustrating a variation of an electronic component. In FIG. 17, the same constituent members as those in FIG. 7 are denoted by the same reference signs, and descriptions thereof will be omitted. An electronic component 52 includes a wiring board 14 and a lid 25. The first assembly 1 is formed by adhering the wiring board 14 to the first sheet 12. An insulating board 141 of the wiring board 14 has a flat plate shape, and has no recessed portion unlike the insulating board 131 of the wiring board 13. The second assembly 2 is formed by adhering a lid 25 to the second sheet 22. Unlike the lid 23, the lid 25 has a cup shape and has a U-shaped cross section. In other words, the lid 25 has a recessed portion on a surface (lower surface) bonded to the wiring board 14. An electronic element 521 is mounted at the central portion of each wiring board 14, and an electrode of the electronic element 521 and an electrode of the wiring board 14 are connected by a wire 522. As illustrated in FIG. 17, the electronic component 52 is obtained by bonding the lid 25 having a cup shape to the wiring board 14 having a flat plate shape.

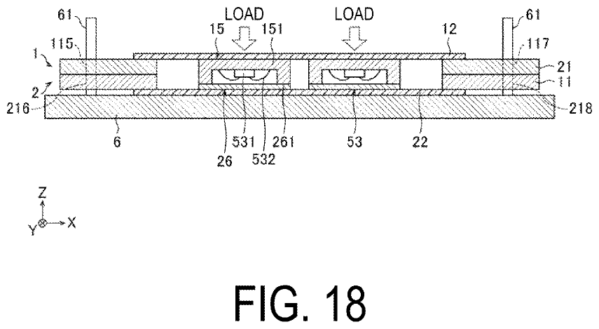

FIG. 18 is a cross-sectional view illustrating another variation of an electronic component. In FIG. 18, the same constituent members as those in FIG. 7 are denoted by the same reference signs, and descriptions thereof will be omitted. The first assembly 1 is formed by adhering a wiring board 15 to the first sheet 12. The wiring board 15 includes an insulating board 151 having a recessed portion and a wiring conductor (not illustrated). The second assembly 2 is formed by adhering a lid 26 to the second sheet 22. Unlike the lid 23, the lid 26 has a wiring conductor (not illustrated) on an insulating board 261 of the lid 26. A wiring conductor of the lid 26 includes an internal wiring and an external terminal. An electronic element 531 is mounted at a central portion of the wiring board 15, and an electrode of the electronic element 531 and an electrode of the wiring board 15 are connected by a wire 532. As illustrated in FIG. 18, an electronic component 53 is obtained by bonding the lid 26 to the wiring board 15. When the wiring board 15 and the lid 26 are bonded to each other, the wiring conductor of the wiring board 15 and the wiring conductor of the lid 26 are electrically connected to each other. In order to facilitate the connection between the wiring conductor of the wiring board 15 and the wiring conductor of the lid 26, each wiring conductor may include a connection pad connected to the internal wiring. The connection pads (wiring conductors) are electrically connected to each other by a conductive bonding material such as solder or a conductive adhesive. The electronic element 531 is sealed by bonding the periphery of the conductive bonding material with a sealing material. The wiring board 15 and the lid 26 may be bonded to each other with an anisotropic conductive adhesive to perform electrical connection and sealing at the same time. As illustrated in FIG. 18, the second assembly 2 may be placed on the bonding table 6 and the first assembly 1 may be overlapped on the second assembly 2.

### Variation of First Manufacturing Method

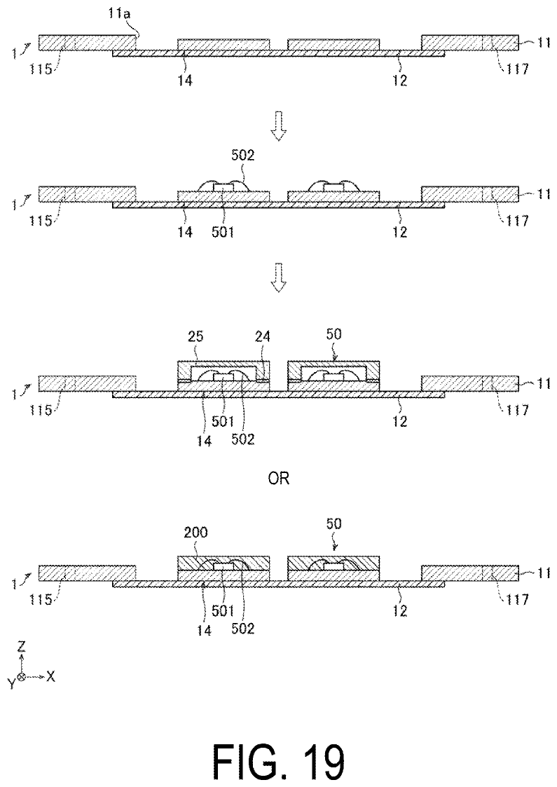

FIG. 19 is a cross-sectional view illustrating a variation of the first manufacturing method of the electronic component 50 described with reference to FIG. 6. This variation is different from the first manufacturing method in the shapes of the wiring board 14, the lid 25, and the resin 200. Unlike the insulating board of the wiring board 13 in the first manufacturing method illustrated in FIG. 6, the insulating board of the wiring board 14 may have a flat plate shape without a recessed portion on the upper surface. Unlike the lid 23 having a flat plate shape, the lid 25 may have a cup shape and may have a U-shaped cross section. In other words, the lid 25 may have a recessed portion on a surface (lower surface) bonded to the wiring board 14. The electronic element 501 is accommodated in a space surrounded by the upper surface of the wiring board 14 and the recessed portion of the lid 25. When the electronic element 501 is sealed with the resin 200, the resin 200 covers the upper surfaces of the electronic element 501 and the wiring board 14. Also in this example, the electronic element 501 can be mounted on the wiring board 14 with high positional accuracy, and the lid 25 can be bonded to the wiring board 14 with high positional accuracy. The singulated electronic component 50 can be manufactured without a cutting process.

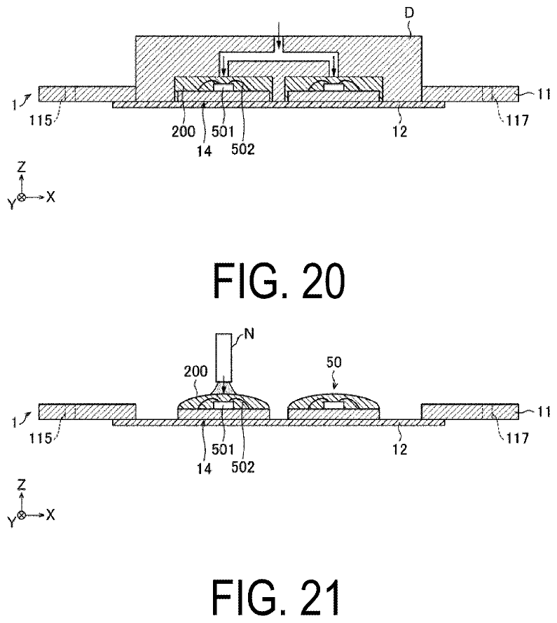

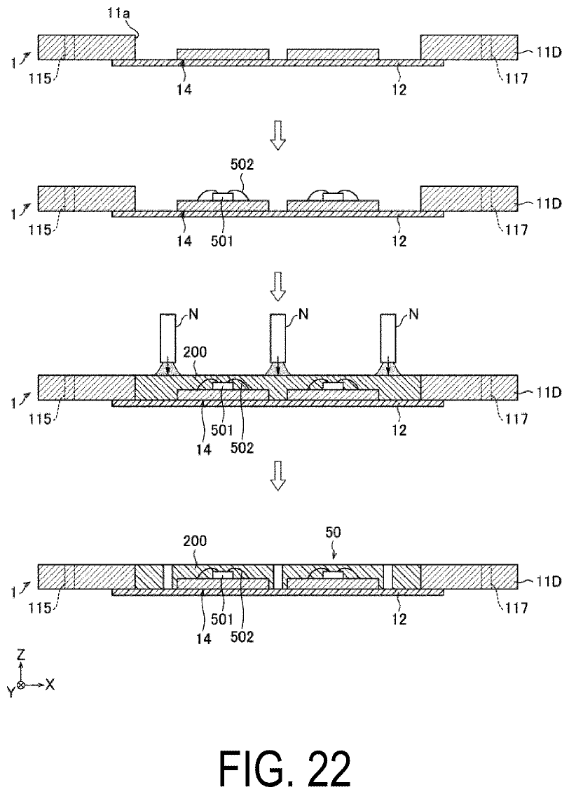

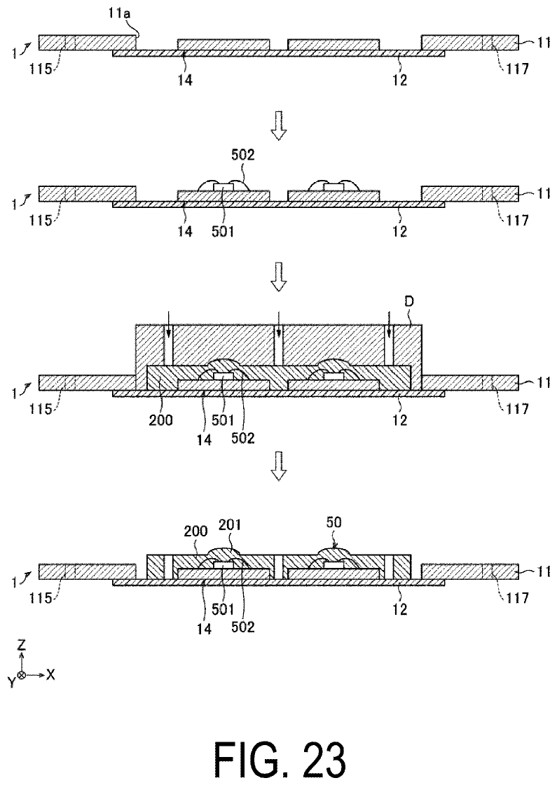

When the electronic element 501 is sealed with the resin 200, each of the plurality of electronic elements 501 may be covered and sealed as in examples illustrated in FIGS. 20 and 21, or the plurality of electronic elements 501 and the wiring board 14 may be collectively covered and sealed as in examples illustrated in FIGS. 22 and 23.

The examples illustrated in FIGS. 20 and 21 are illustrated in views for explaining the step of sealing the electronic element 501 with the resin 200 in the method for manufacturing the electronic component illustrated in FIG. 19. FIGS. 20 and 21 illustrate a method for individually resin-sealing the plurality of wiring boards 14 on which the electronic elements 501 are mounted. Arrows in these views indicate the flow of the resin 200 from a mold D or a nozzle N.

The example illustrated in FIG. 20 is a method for performing resin sealing by molding using the mold D. The shape of the upper surface of the electronic component 50 can be formed into a desired shape by the shape of the mold D. For example, by making the upper surface of the electronic component 50 flat, the electronic component 50 having a good picking property by a suction nozzle or the like can be manufactured. The side surface of the wiring board 14 may also be covered with the resin 200. Only the upper surface of the wiring board 14 or only a central portion of the upper surface of the wiring board 14, where the electronic element 501 is mounted, may be covered with the resin 200.

The example illustrated in FIG. 21 is a resin-sealing method using a potting method in which a liquid resin 200 is dropped from the nozzle N or the like to cover the electronic element 501 with the resin 200. The resin 200 may also be supplied onto each wiring board 14 by a printing method using a mask. A frame-shaped mold for stopping the flow of the resin 200 may be provided around each wiring board 14. By removing the mold after the resin 200 is cured, the electronic component 50 having a flat upper surface can be manufactured. The resin 200 may cover up to the side surface of the wiring board 14, or only a central portion of the upper surface of the wiring board 14, where the electronic element 501 is mounted, may be covered with the resin 200.

Each of the examples illustrated in FIGS. 22 and 23 is a cross-sectional view illustrating another example of the method for manufacturing the electronic component, and is a variation of the method for manufacturing the electronic component illustrated in FIGS. 6 and 19. This variation is an example in which the step of sealing the electronic element 501 in the first manufacturing method covers the electronic element 501 with the resin 200 to seal the electronic element 501. FIGS. 22 and 23 illustrate a method for collectively covering the plurality of electronic elements 501 and the wiring board 14 with a resin 200 as a sealing resin to seal the electronic elements 501.

FIG. 22 is a view for explaining a method for covering the plurality of wiring boards 14, where the electronic elements 501 are mounted, with the liquid resin 200 by dropping the resin 200 from the nozzle N or the like. As in this example, a first frame body 11D may be used as a mold for stopping the flow of the resin 200. The first frame body 11D is thicker than the first frame body 11 of the example illustrated in FIG. 6. The thickness of the first frame body 11D may be equal to or greater than the height (thickness) of the electronic component 50. By using such a first frame body 11D, the electronic element 501 can be covered and the upper surface of the electronic component 50 can be made flat. By using the first frame body 11 similar to the example illustrated in FIG. 6, a mold having a thickness similar to the thickness of the first frame body 11D, that is, a mold thicker than the first frame body 11 and equal to or greater than the height of the electronic component 50 may be disposed inside the first frame body 11. Instead of supplying the resin 200 by the nozzle N, the resin 200 may be supplied onto each wiring board 14 by a printing method using a mask. The resin 200 may cover not only the wiring board 14 but also the first sheet 12 around the wiring board 14. After the resin 200 is cured, the electronic components 50 can be manufactured by cutting the resin 200. For example, the resin 200 can be cut along the outer edge of each wiring board 14 by dicing or the like. Although a cutting step after sealing is added to the first manufacturing method, only the resin 200 between the wiring boards 14 is cut. Since only the relatively soft resin 200 is cut, highly accurate cutting is possible. In order to completely cut the resin 200, a part of the first sheet 12 located below the resin 200 is also cut; however, since the first sheet 12 is also made of resin, cutting can be easily performed with high accuracy. Since the stress applied to an interface between the wiring board 14 and the resin 200 at the time of cutting is small, the possibility that the resin 200 is peeled off from the wiring board 14 is reduced and the electronic component 50 having good sealing properties can be manufactured.

FIG. 23 illustrates a method for collectively covering and sealing the plurality of electronic elements 501 with the resin 200 similarly to FIG. 22, but the method for supplying the resin 200 is different. In this method, resin sealing is performed by molding using the mold D. The resin 200 may cover not only the wiring board 14 but also the first sheet 12 around the wiring board 14. After the resin 200 is cured, the electronic components 50 can be manufactured by cutting the resin 200. For example, the resin 200 can be cut along the outer edge of each wiring board 14 by dicing or the like. Although a cutting step after sealing is added to the first manufacturing method, only the resin 200 between the wiring boards 14 is cut. Since only the relatively soft resin 200 is cut, highly accurate cutting is possible. In order to completely cut the resin 200, a part of the first sheet 12 located below the resin 200 is also cut; however, since the first sheet 12 is also made of resin, cutting can be easily performed with high accuracy. Since the stress applied to an interface between the wiring board 14 and the resin 200 at the time of cutting is small, the possibility that the resin 200 is peeled off from the wiring board 14 is reduced and the electronic component 50 having good sealing properties can be manufactured.

In this way, in the step of sealing the electronic elements 501 in the first manufacturing method, the plurality of electronic elements 501 and the wiring board 14 are collectively covered with the resin 200 to seal the electronic elements 501, and this method may be a method for manufacturing an electronic component further including a step of cutting the resin 200 around the wiring board 14. Regarding the positional accuracy and the amount of the resin 200 with respect to the electronic element 501 and the wiring board 14, the electronic element 501 can be covered and easily sealed with the resin 200 without precisely controlling the position of the nozzle N, the discharge amount of the resin 200 from the nozzle N, and the position of the mold D. In particular, when the electronic component 50 (the wiring board 14 and the electronic element 501) is small, the manufacturing of the electronic component 50 is facilitated. Also by this manufacturing method, the electronic element 501 can be mounted on the wiring board 14 with high positional accuracy.

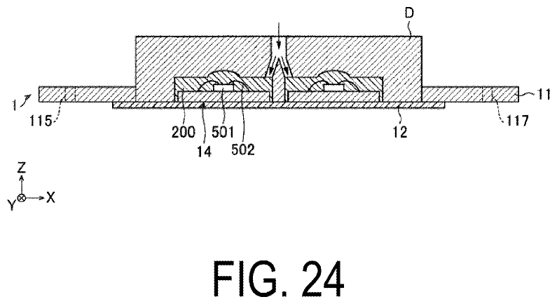

In the method for manufacturing an electronic component using the mold D illustrated in FIG. 23, a part of the upper surface of the electronic component 50 (resin 200) has a protruding portion 201 protruding in a convex curved surface shape. The shape of the upper surface of the electronic component 50 can be formed into a desired shape by the shape of the mold D. For example, when the electronic element 501 is an optical element such as a light-emitting element, an optical member such as a lens can be formed by the protruding portion 201 formed in the resin 200. The resin 200 at this time can transmit light from the light-emitting element, for example, and when the light is visible light, a transparent resin can be used as the resin 200. By multi-color molding, a transparent resin can be disposed only above the light-emitting element (electronic element 501) and an opaque resin can be disposed around the light-emitting element. In this way, when the plurality of wiring boards 14 of the first assembly 1 are collectively resin-sealed using the mold D, not only the mounting and sealing of the electronic element 501 but also the mounting (formation) of the optical member can be performed with high positional accuracy. The positional accuracy between the optical member and the optical element (electronic element 501) is good, and an optical component (electronic component 50) having excellent optical characteristics can be efficiently manufactured. FIG. 23 illustrates an example in which the protruding portion 201 is a convex lens; however, the present disclosure is not limited thereto. Instead of the protruding portion 201, a recessed portion such as a groove may be formed. By forming such irregularities, a product number or the like of the electronic component 50 can be marked. A mark indicating a cutting position at the time of cutting can also be formed. Also in the method for individually resin-sealing the plurality of wiring boards 14 by using the mold D as illustrated in FIG. 20, the shape of the upper surface of the electronic component 50 can be formed into a desired shape by the shape of the mold D as illustrated in FIG. 24.

In the present disclosure, the invention has been described above based on the drawings and embodiments. However, the invention according to the present disclosure is not limited to each embodiment described above. That is, the embodiments of the invention according to the present disclosure can be modified in various ways within the scope illustrated in the present disclosure, and embodiments obtained by appropriately combining the technical means disclosed in different embodiments are also included in the technical scope of the invention according to the present disclosure. In other words, a person skilled in the art can easily make various variations or modifications based on the present disclosure. Note that these variations or modifications are included within the scope of the present disclosure.

In the above embodiment, the case where the package set 3 includes the first assembly 1 and the second assembly 2 has been described, but the present disclosure is not limited thereto. The first assembly 1 may have a flat plate-like wiring board 13, the second assembly 2 may include a flat plate-like lid 23, and the package set may further include a third frame, a third sheet, and a rectangular frame member. The frame member is a member interposed between the wiring board 13 and the lid 23. A frame member may be adhered to the third sheet at a position corresponding to the wiring board 13 and the lid 23. A third assembly may be overlapped on the first assembly 1 so that the frame member is opposite to the wiring board 13, and the frame member may be bonded to the wiring board 13. Subsequently, the second assembly 2 may be overlapped on the third assembly so that the lid 23 is opposite to the frame member, and the lid 23 may be bonded to the frame member.

### REFERENCE SIGNS

1 First assembly
11, 11D First frame body
11a, 11c Opening
12 First sheet
13, 14, 15 Wiring board
131, 141, 151 Insulating board
132 Wiring conductor
501, 521, 531 Electronic element
502, 522, 532 Wire
2 Second assembly
21 Second frame body
21a, 21c Opening
22, 28, 29, 30 Second sheet
23, 25, 26 Lid
24 Sealing material
3 Package set
50, 52, 53 Electronic component

1. A wiring board assembly comprising:
a frame body;
a sheet configured to close the frame body; and
a plurality of wiring boards adhered to one surface of the sheet.

2. A lid assembly comprising:
a frame body;
a sheet configured to close the frame body; and
a plurality of lids adhered to one surface of the sheet.

3. A package set comprising:
the wiring board assembly comprising:
a first frame body;
a first sheet configured to close the first frame body; and
a plurality of wiring boards adhered to one surface of the first sheet; and
the lid assembly comprising:
a second frame body;
a second sheet configured to close the second frame body; and
a plurality of lids adhered to one surface of the second sheet, wherein
the plurality of lids are located on the one surface of the second sheet in correspondence with the plurality of wiring boards.

4. The package set according to claim 3, wherein an adhesive strength of the sheet of the wiring board assembly with respect to the plurality of wiring boards is different from an adhesive strength of the sheet of the lid assembly with respect to the plurality of lids.

5. The package set according to claim 3, wherein at least one of the first sheet assembly and the second sheet is a UV release sheet or a thermal release sheet.

6. The package set according to claim 4, wherein a sheet having a higher adhesive strength among the first sheet and the second sheet is a UV release sheet or a thermal release sheet.

7. The package set according to claim 3, wherein the second sheet is a thermal release sheet.

8. The package set according to claim 3, wherein the first frame body and the plurality of wiring boards are located on an identical surface of the first sheet, and the second frame body and the plurality of lids are located on an identical surface of the second sheet.

9. The package set according to claim 3, wherein the first frame body of at least one of the first or second sheets is located on a surface opposite to the plurality of wiring boards or the plurality of lids.

10. The package set according to claim 3, wherein the first frame body and the second frame body each comprise an alignment portion configured to align a position of the wiring board assembly to a position of the lid assembly.

11. The package set according to claim 3, wherein any one of the first or second sheets comprises a hole at a position corresponding to each of the plurality of wiring boards or each of the plurality of lids.

12. The package set according to claim 3, wherein the first frame body comprises a notch or a through hole configured to expose a peripheral edge of the sheet.

13. A method for manufacturing an electronic component, the method comprising:
preparing a wiring board assembly comprising a first frame body, a first sheet configured to close the first frame body, and a plurality of wiring boards adhered to one surface of the first sheet;
mounting each of a plurality of electronic elements on a respective wiring board of the plurality of wiring boards of the wiring board assembly;
sealing the plurality of electronic elements; and
peeling off the plurality of wiring boards from the first sheet.

14. A method for manufacturing an electronic component, the method comprising:
preparing a wiring board assembly comprising a first frame body, a first sheet configured to close the first frame body, and a plurality of wiring boards adhered to one surface of the first sheet;
preparing a lid assembly comprising a second frame body, a second sheet configured to close the second frame body, and a plurality of lids adhered to one surface of the second sheet;
mounting each of a plurality of electronic elements on a respective wiring board of the plurality of wiring boards of the wiring board assembly;
overlapping the lid assembly on the wiring board assembly, the plurality of lids of the lid assembly being opposite to the plurality of wiring boards on which the plurality of electronic elements are mounted;
sealing the electronic elements by bonding the plurality of lids to the plurality of wiring boards;
peeling off the plurality of wiring boards from the first sheet; and
peeling off the plurality of lids from the second sheet.

15. The method according to claim 14, wherein
the second sheet is a UV release sheet having a higher adhesive strength than the first sheet, and
the method further comprises peeling off the plurality of lids from the second sheet by radiating UV after the plurality of wiring boards are peeled off from the first sheet.

16. The method according to claim 14, wherein
the first sheet or the second sheet comprises a hole at a position corresponding to each of the plurality of wiring boards or each of the plurality of lids, and
the method further comprises peeling off the plurality of wiring boards or the plurality of lids from the first sheet or the second sheet by inserting a jig into the hole and pressing the plurality of wiring boards or the plurality of lids.

17. The method according to claim 14, wherein
the first frame body or the second frame body comprises a notch or a through hole at a peripheral edge, and the first sheet or the second sheet is adhered to the first frame body or the second frame body, the first sheet or the second sheet being exposed from the notch or the through hole, and
the method further comprises peeling off the first sheet or the second sheet from the first frame body or the second frame body by gripping the first sheet or the second sheet from the notch or the through hole after the plurality of wiring boards or the plurality of lids are peeled off from the first sheet or the second sheet.

18. The method according to claim 13, wherein
in the sealing of the plurality of electronic elements, the plurality of electronic elements and the plurality of wiring boards are collectively covered with a resin to seal the plurality of electronic elements, and
the method further comprises cutting the resin around the plurality of wiring boards.
